(19) United States
(12) Patent Application Publication
(10) Pub. No.: US 2013/0206590 A1
(43) Pub. Date: Aug. 15, 2013

(54) Manufacture of High Density Indium Tin Oxide (ITO) Sputtering Target

(71) Applicant: Dotsen Baluch, Pinner (GB)

(72) Inventor: Dotsen Baluch, Pinner (GB)

(73) Assignee: Sinito (Shenzhen)Optoelectrical Advanced Materials Company Limited, Shenzhen City (CN)

(21) Appl. No.: 13/813,217

(22) PCT Filed: Aug. 5, 2011
(86) PCT No.: PCT/IB2011/001818

§ 371 Date: Apr. 16, 2013

(30) Foreign Application Priority Data
Aug. 6, 2010 (GB) 1013255.3

(51) Int. Cl. C23C 14/34

(52) U.S. Cl. CPC C23C 14/3414
USPC 204/298.13; 264/651; 264/129

(57) ABSTRACT

A process for manufacturing indium tin oxide (ITO) sputtering targets is provided. The process includes: precipitating indium and tin hydroxides, calcining the hydroxides to produce granulated ITO powder, preparing an aqueous slurry of the ITO powder with additives such as special sintering aids, dispersing agent and binders, milling the slurry to obtain a slip, preparing compacted ITO green bodies by casting the slip using porous molds or drying the slip to yield granulated ITO powder and cold isostatic pressing the powder, and sintering the green body to yield ITO target of high density greater than 99% of theoretical.

### CROSS REFERENCE TO RELATED APPLICATION

The present application claims priority to (is a national stage filing of) PCT Application PCT/IB2011/001818 filed Aug. 5, 2011, which claims priority to British Patent Application No. GB1013255.3 filed Aug. 6, 2010. The entirety of each of the aforementioned references is incorporated herein by reference for all purposes.

### FIELD OF THE INVENTION

This invention relates to a method of manufacturing indium tin oxide (ITO) sputtering targets. In particular, the invention relates to compacting of ITO powders and subsequent sintering to obtain high density ITO targets.

### BACKGROUND OF THE INVENTION

ITO exhibits a remarkable combination of optical and electrical transport properties: (i) high electrical conductivity (≈10⁴ Ω⁻¹ cm⁻¹) and (ii) high optical transparency (>85%) in the visible range of the spectrum. This makes ITO a Transparent Conducting Oxide (TCO) whose thin films on glass and plastic sheets are optically transparent and, at the same time, offer high electrical conductivity. This forms the basis of ITO's use in flat panel displays such as Liquid Crystal Displays (LCD) and photovoltaic solar cell panels where ITO functions as a transparent electrical conductor or electrode. An additional attractive property of ITO is that its thin films are stable and retain their properties over a long period of time.

In the prior art, ITO is the standard mainstream TCO material used for the fabrication of transparent electrodes for displays and solar cells. In the prior art processes: (i) the ITO is formed into a sputtering target which is then used to sputter thin films (≈2 μm thick) on glass or plastic sheets and (ii) for display circuits, the ITO film is converted into a transparent circuit by etching using chemical lithographic methods whereas for solar cells it is used without etching as a uniform planar top electrode. The method of sputtering is a process in which material is removed from an ITO target (the cathode) by ion bombardment, carried by a plasma in a high vacuum and deposited on a glass sheet (the anode), as shown in FIG. 1.

The industry standard sputtering method requires an ITO sputtering target which is a rectangular shaped body of high density ITO material of metallic grey looking appearance. In general, the ITO target manufacturing process comprises: (i) manufacture of high purity 5N indium and tin metal by refining, (ii) production of 5N ITO powder, (iii) production of ITO slurry containing additives, (iv) conversion of the ITO slurry into slip using mechanical milling, (v) production of ITO green bodies (the term ‘green body’ denotes a pre-fired ceramic body) by casting or pressing and (vi) sintering of ITO green bodies by firing in a furnace to produce dense ITO targets (see FIG. 2). In the final process of sintering, the grains in the green body fuse to give larger grains thereby increasing the density. This is accompanied by considerable shrinkage of the green body.

It is known in the prior art that the presence of impurities in the ITO green body can enhance the sintering process. These impurities are deliberately added to the ITO powders prior to compaction and they are known as ‘sintering aids’. Common sintering aids include oxides of silicon and rare earth metals. However, ITO is a difficult material to sinter and the common sintering agents cited in the prior art do not enhance sintering sufficiently to produce large ITO targets of uniform density greater than 99% of the theoretical density in high production yields. It is enormously challenging to achieve ITO target densities of >99% of theoretical across large target surfaces such as those required by the TFT-LCD industry.

The high and uniform density of the ITO target is very important to obtaining satisfactory sputtering and an ITO thin film of quality sufficient for use in LCD related applications especially LCD's based on T in Film Transistors (TFT) where ITO target size requirements are large being ≧250 cm².

If the target density is not >99% of theoretical and not uniform, then problems are encountered during the ITO sputtering process. In the sputtering process, the target is subject to high power densities that also lead to high surface temperatures. The high power densities are needed to achieve economically viable thin film deposition rates in the TFT-LCD production processes. The high surface temperatures mean that the ITO target requires cooling during use. This is achieved by bonding one face of the rectangular ITO target to a copper plate. The copper plate is also used to apply a voltage to the ITO target and achieve high powder densities on the target. The copper plate is bolted down onto a metal block with a central cavity under the copper plate and water is circulated through the cavity. The copper plate serves as a heat sink that extracts heat from the ITO target thus preventing the target from melt down.

It will be apparent to those skilled in the art that if the density is not high and not uniform across the target than there will be a non-uniformity in the sputtering rate across the target surface leading to quality defects on the target surface such as hot spots and nodules. In turn, these can lead to quality defects in the ITO thin film.

Thus, it is known to those skilled in the art that the achievement of high and uniform densities across large target surface is of paramount importance. It is also known to those skilled in the art that densities of >99% of theoretical densities are needed. The challenge in achieving such high densities uniformly across a large ITO target is that ITO is a difficult material to sinter. For successful uniform sintering, the grain boundaries in the ITO green body are required to fuse leading to increase in grain sizes and considerable shrinkage of the green body accompanied by density increases.

In the prior art, considerable effort has gone into: (1) achieving large ITO green bodies of uniform and optimum green densities and (2) developing methods for achieving satisfactory sintering of the green body.

In one method of the prior art, ITO green bodies are prepared by molding ITO powder by pressure molding processes such as a hot isostatic pressing (HIP) (U.S. Pat. No. 6,099,982; U.S. Pat. No. 6,123,787) or cold isostatic pressing (CIP) (U.S. Pat. No. 5,531,948). In HIP, the ITO powder is shaped under high pressure and temperature thus causing sintering to yield a dense sintered ITO body. In the cold isostatic pressing method, the ITO powder is molded into a shaped body by cold pressing followed by firing the shaped body in a furnace at high temperatures in the range 1400 to 1750° C. to yield a dense sintered ITO target.

In another method of the prior art, ITO green bodies are prepared by a method known as pressureless slip casting. These are then fired in a furnace at high temperature to achieve sintering. In one slip casting method (JP1117136/88; JP117137/88; JP117138/88), the indium oxide and tin oxide powders are mixed in a liquid such as water with a dispersing agent and a binder followed by milling using mechanical milling methods to give a slurry called ‘slip’ which is injected into a water absorbing porous mould made of gypsum or plaster of paris. The slurry in the mold then slowly dries as the water leaves the mold via the mold pores. The dispersing agent used is, for example, selected from polycarboxylic acids and the binder is selected, for example, from acrylic emulsions. In this method, the slip is injected into a mold under pressure in the range 50 to 200 kPa. Further increases in green body density are obtained by subjecting the green body to cold isostatic pressing which applies a pressure not less than 100 MPa. The ITO target is then sintered at 1300 to 1400° C. to obtain a dense target with densities greater than 95%. However, this prior art suffers from the problem that the yield of targets with densities greater than 99% is low. Furthermore, during filling of the gypsum or plaster of paris moulds, the mould material can enter the slip or adhere to the ITO “green body” tile resulting in contamination of the target by the mold material. These impurities then lead to reduction in the ITO thin film conductivity and problems in the sputtering process such as, for example, the formation of nodules.

In another method (JP 2005324987) for preparing green bodies and then sintering and avoiding the use of slip casting molds during manufacture, indium and tin oxide powders, water and an organic binder are mixed, milled and then spray dried to yield a granulated powder which is then high pressure press molded to yield a green body. The latter is sintered to yield dense ITO target.

In another embodiment of the prior art (JP10330926), the density of the target is regulated to achieve ≧99% and also the maximum diameter of voids existing in the sintered target are regulated to less than or equal to 10 microns with less than 1000 voids in one mm² area of the target. This is achieved by co-precipitation of indium and tin oxides and then calcining the oxides in an atmosphere containing hydrogen halide gas such as hydrogen chloride or halogen gas such as chlorine. The powders are then molded into a compact green body by slip casting and firing the green body. In this way, targets of size greater than 100 cm² can be obtained with claimed densities ≧99%. However, this method is enormously hazardous due to the use of highly poisonous and unstable gases.

The above methods of the prior art use oxides of silicon or yttrium or zirconium as sintering aids. These function by introducing instability at the grain boundaries that encourage break down and fusion of grain boundaries. However, as stated earlier, ITO is a difficult material to sinter and the sintering aids known in the prior art are not sufficient to enable manufacture of large ITO targets of high and uniform densities in high production yields.

### BRIEF SUMMARY OF THE INVENTION

The object of the present invention is to provide a process for readily achieving high and uniform density, preferably greater than 99% of the theoretical, particularly in large targets (preferably ≧250 cm²) for high utilization efficiency particularly in LCD related sputtering applications.

This objective is obtained by a method that involves (at least in the preferred embodiments) the co-precipitation of indium and tin oxides from acidic solutions such as hydrochloric or nitric acid solutions, filtering, washing and calcining the oxides, preparation of an aqueous slurry of the oxides with additives such as dispersing agent, binder, special sintering aids based on compounds of arsenic, antimony, bismuth, selenium, tellurium and/or boron, milling the slurry to obtain a ‘slip’ of the right particle size distribution and particle surface area, compacting the slurry using slip casting in a specially sugar and chelating agent coated plaster of paris porous mold or pressure slip casting at pressures of up to 40 bar in a porous plastic mold and then sintering the resultant compacted ITO green body in an oxygen atmosphere to yield a dark grey high density (>99% of theoretical density) ITO target.

In accordance with one aspect of the present invention there is provided a method of producing granulated ITO powder for use in the manufacture of ITO sputtering targets. An intimate mixture of indium and tin hydroxide powders is calcined in air. The calcination may be carried out at a temperature in the range 800° C.-1200° C., more preferably 1000° C. The resultant granulated ITO powder is used for the manufacture of the ITO targets.

In accordance with another aspect of the present invention there is provided a method of forming an ITO slip for use in the manufacture of ITO sputtering targets. A slurry comprising granulated ITO powder, water and additives is formed. Additives include compounds of boron, arsenic, antimony, bismuth, selenium or tellurium or mixtures thereof in the slurry in a concentration between 0.001% and 1% by weight. The slurry is then subjected to mechanical milling to yield the ITO slip. The compounds of these elements without limitation can be their oxides, acids, or their compounds with indium such as indium antimonide, indium arsenide, indium selenide or indium telluride. These boron, arsenic, antimony, bismuth, selenium, tellurium compounds interact during sintering with indium oxide in the ITO green body and form compounds such as indium antimonide, indium arsenide, indium selenide, indium telluride. These indium compounds form a glassy liquid phase at temperatures below the sintering temperatures of ITO. The presence of these liquid phases at ITO grain boundaries facilitates ITO grain fusion leading to enhanced sintering, larger grains and higher densities. Additionally, these compounds of arsenic, antimony, bismuth, selenium and tellurium can interact with other additives in the slip such as silicates to form glassy silicate compounds which are also liquid phase below the sintering temperatures and can also facilitate fusion of ITO grain boundaries. In this way, these compounds act as ITO sintering aids and high density promoters in the sintering process, readily leading to higher densities of greater than 99% in the ITO target.

According to the present invention, the granulated ITO powder used to make the slip, preferably comprises indium(III) and tin(IV) oxides of surface area 1-5 m²/g. The oxides are present in the slip in concentrations in the range >75% weight percent. The slip may also contain a binder such as an acrylic emulsion and/or a dispersing agent such as a polycarboxylic acid and common sintering aids such as silicon dioxide.

The slip may then be slip cast by injection into a porous mold and left at ambient temperatures to form a “green body”. The green body is then dried and subsequently fired at high temperatures of >1400° C. in an oxygen atmosphere to achieve sintering. It is at this stage that the presence of sintering aids that are present as a glassy liquid phase at the ITO grain boundaries facilitates sintering leading to large grains and high density in the target.

In accordance with a further aspect of the present invention there is provided a method of manufacturing an ITO sputtering target. A porous mold of gypsum or plaster of paris is coated with a layer of a sugar or starch release agent. An ITO slip is then injected into the mold at pressures of 0.1 to 45 psi.

Alternatively, the slip can be injected into a porous polymer mold and slip cast at high pressures of up to 10 MPa.

The green body is dried for several days at 50° C. and then fired at a temperature between approximately 1000° C. and 1700° C. in an oxygen atmosphere.

It will be appreciated that the various aspects of the invention may be combined.

### BRIEF DESCRIPTIONS OF THE DRAWINGS

FIG. 1 is a schematic illustration of a sputtering process.

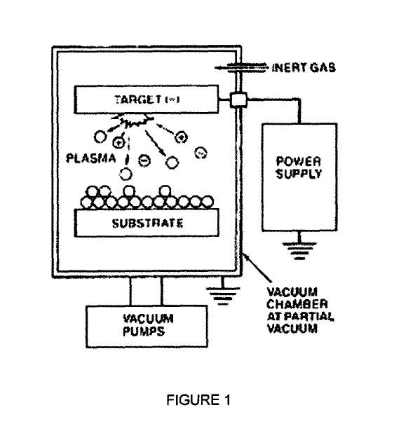

FIG. 2 is a flow chart illustrating the steps involved in manufacturing an ITO target.

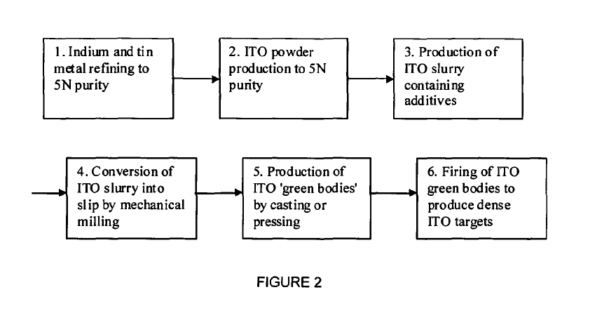

### DETAILED DESCRIPTION OF THE PREFERRED EMBODIMENTS

In order that the present invention may be fully understood and readily put into practical effect, there shall now be described by way of non-limitative example only preferred embodiments of the present invention.

After intensive investigations of the prior art and problems achieving high and uniform density in large targets for TFT-LCD applications, the present inventors have succeeded in developing methods based on novel sintering aids that can readily give large targets of densities >99% without the use of hazardous gases of the prior art such hydrogen chloride or chlorine nor require cold isostatic pressing to achieve high and uniform densities.

The improved process enables production of ITO sputtering targets of large size ≧250 cm² that give ITO thin films of quality suitable for TFT-LCD industry and offer high target utilization rates by overcoming problems such as nodule formation, target cracking, non-uniform properties across target body and abnormal electric discharges during sputtering.

ITO targets are produced that contain indium(III) oxide and tin(IV) oxide where the indium(III) oxide content is not less than 75% by weight. Also, the presence of a third component other than the oxides of indium and tin is permitted for attaining high and uniform target densities whilst minimizing target cracking. Such a third component preferably comprises compounds of boron, arsenic, antimony, bismuth, selenium and/or tellurium.

In a first stage of the process, indium and tin oxides are precipitated in chloride media, filtered, washed and calcined at 800-1200° C. The resultant granulated indium and tin oxide powder with surface area in the range 1 to 5 m²/g, preferably 4 m²/g, is made into a slurry with water such that the concentration of the oxides is not less than 75% by weight and more preferably in the range 75-85%. The slurry also contains dispersion agents for example such as polycarboxylic acids in concentrations of 0.1 to 2% by dry basis mass of the ITO powder and binders in concentrations of 0.1 to 5% by dry basis mass of the ITO powder for examples acrylic emulsions, though not specifically limited to these compounds. The slurry additionally contains compounds of boron, arsenic, antimony, bismuth, selenium and/or tellurium or mixtures thereof. Such compounds can include the respective oxides or acids of these elements or their compounds with indium such as indium arsenide, indium antimonide, indium selenide and indium telluride. The concentrations of these compounds in the slurry is in the range 0.001% to 1% by dry basis mass of the ITO powder used. The slurry may also contain common sintering aids such as silicone dioxide in the range 0.001% to 1% by dry basis mass of the ITO powder used.

The slurry is converted into a slip suitable for slip casting by mechanical milling using either a bead mill, attirition mill or a ball mill. The milling is conducted until the ITO particles have reached a particle size distribution of such that the particles sizes are in the range 50-800 nm and the surface area in the range 7.5 to 9.5 m²/g. The viscosity of such slip is in the range 500 to 1400 cps as measured by a Brookfield rheometer using spindle 65 at a spindle speed of 25 rpm.

The slip so obtained is then filtered through a 0.5 micron filter and then injected into a porous mold made of materials such as gypsum, Plaster of Paris or porous polymers. Where gypsum or Plaster of Paris are used as mould materials, the molds are coated with a thin layer of a releasing agent such as a sugar or starch. The filled molds are left at ambient temperatures. The material of the slip compacts into a dense shape green body by capillary forces induced via the water absorbing action of the porous mold.

The slip may be injected at high pressures of up to 10 MPa into a porous polymer mold fixed in a commercial pressure slip casting machine. After a casting time of 10 to 40 minutes, the mold is opened and the cast green body is removed from the mold.

The slip may then be spray dried at temperatures of 80-110° C. to yield a granulated ITO powder which is subjected to cold isostatic pressing at pressures of 80-110 MPa to yield a compacted green body.

The green body obtained is then dried in an oven in the temperature range 40-80° C. for 3-5 days and then fired in a furnace at temperatures of 1000° C.-1750° C. in an oxygen atmosphere. The shape and size of the target is not limited and can be altered simply by altering the shape and size of the mold and molds of size >100 cm² can be used. Further targets of the desired dimension and size can be obtained without suffering any crack and bending.

According to the processes of the present invention, ITO targets can be prepared with relative density ≧99%.

### EXAMPLES OF EMBODIMENTS

### Example 1

Indium(III) and tin(IV) oxides were co-precipitated from solutions of their nitrate compounds. Washing of the precipitates was conducted with deionised water. The precipitated hydroxides were filtered and then calcined at 800° C. to 1200° C. to yield oxide powders with surface areas in the range 1 to 5 m²/g. A Plaster of Paris mould of dimensions 1000 mm×700 mm and cavity thickness of 20 mm was sprayed lightly with a 10% sugar dispersion. A slurry containing 96000 g of ITO powder 99.999% pure of surface area 3.5 m²/g and composition indium(iii) oxide 90% by weight, 1800 g of 22% by weight solution of polycarboxylic acid dispersing agent such as Daravan C, 500 g of acrylic emulsion binder of 55% by weight concentration, 140 g of an oxide such as MxOy (where M=arsenic, antimony, bismuth and X=2, Y=3; M=selenium, tellurium and X=1 and Y=2) and 10000 g of deionised water were placed in a high density polypropylene pot of 50000 liter capacity and the whole mixture was thoroughly mixed for 72 hours with a rotating ball mill using yttria stabilized zirconia beads of 12 mm diameter to obtain a slip of intimately blended ITO powder with surface area 9 m²/g for slip casting the ITO green bodies.

The slip obtained was thoroughly de-aired using ultrasonic agitation and then injected into the porous plaster of paris mold under pressures of 30 psi. The pressure was maintained for 4 hours. After this period, the pressure was removed and the mold was opened. The ITO green body was taken out, dried at 25° C. for 7 days and then at 50° C. for 7 days. It was then fired in an oxygen atmosphere at 1700° C. for 10 hours. The fired highly dense ITO target was precision cut, surface machined, cleaned in high purity isopropyl alcohol and air dried to give a commercial working target ready for bonding to a copper backing plate and use in a sputtering process. All above operations were performed in a Class 10000 clean room.

The target obtained had relative density of 99.5%.

### Example 2

Indium(III) and tin(IV) oxides were co-precipitated from solutions of their nitrate compounds. Washing of the precipitates was conducted with deionised water. The precipitated hydroxides were filtered and then calcined at 800° C. to 1200° C. to yield oxide powders with surface areas in the range 1 to 5 m²/g. A slurry containing 96000 g of ITO powder 99.999% pure of surface area 3.5 m²g and composition indium(iii) oxide 90% by weight, 1800 g of 22% by weight solution of polycarboxylic acid dispersing agent such as Daravan C, 500 g of acrylic emulsion binder of 55% by weight concentration, 140 g of an oxide such as MxOy (where M=arsenic, antimony, bismuth and X=2, Y=3; M=selenium, tellurium and X=1 and Y=2) and 10000 g of deionised water were placed in a high density polypropylene pot of 50000 liter capacity and the whole mixture was thoroughly mixed for 72 hours with a rotating ball mill using yttria stabilized zirconia beads of 12 mm diameter to obtain a slip of intimately blended ITO powder with surface area 9 m²/g. The slip was injected into a porous polymer mold of dimensions 1500 mm×800 mm×20 mm fixed in a pressure slip casting machine and cast for 10 to 30 minutes at pressure of 10 MPa. The mold was then opened and the cast green body removed from the mold.

The ITO green body was dried at 25° C. for 7 days and then at 50° C. for 7 days. It was then fired in an oxygen atmosphere at 1700° C. for 10 hours. The fired highly dense ITO target was precision cut, surface machined, cleaned in high purity isopropyl alcohol and air dried to give a commercial working target ready for bonding to a copper backing plate and use in a sputtering process. All above operations were performed in a Class 10000 clean room.

The target obtained had relative density of 99.8%.

### Example 3

Indium(III) and tin(IV) oxides were co-precipitated from solutions of their nitrate compounds. Washing of the precipitates was conducted with deionised water. The precipitated hydroxides were filtered and then calcined at 800° C. to 1200° C. to yield oxide powders with surface areas in the range 1 to 5 m²/g. A slurry containing 96000 g of ITO powder 99.999% pure of surface area 3.5 m²/g and composition indium(iii) oxide 90% by weight, 1800 g of 22% by weight solution of polycarboxylic acid dispersing agent such as Daravan C, 500 g of acrylic emulsion binder of 55% by weight concentration, 140 g of an oxide such as MxOy (where M=arsenic, antimony, bismuth and X=2, Y=3; M=selenium, tellurium and X=1 and Y=2) and 10000 g of deionised water were placed in a high density polypropylene pot of 50000 liter capacity and the whole mixture was thoroughly mixed for 72 hours with a rotating ball mill using yttria stabilized zirconia beads of 12 mm diameter to obtain a slip of intimately blended ITO powder with surface area 8.5 m²/g. The slip was spray dried by using a spray dried operating at 110° C. to yield granulated ITO powder which was then compacted in a stainless steel mold of diameter 1500 mm using cold isostatic pressing at pressures of 120 MPa to yield an compacted ITO green body.

The ITO green body was dried at 25° C. for 7 days and then at 50° C. for 7 days. It was then fired in an oxygen atmosphere at 1700° C. for 10 hours. The fired highly dense ITO target was precision cut, surface machined, cleaned in high purity isopropyl alcohol and air dried to give a commercial working target ready for bonding to a copper backing plate and use in a sputtering process. All above operations were performed in a Class 10000 clean room.

The target obtained had relative density of 99.9%.

### Example 4

Using the same method as in Examples 1, 2 and 3 except that 140 g of indium arsenide was added to the slurry. The target obtained had relative density of 99.2%.

### Example 5

Using the same method as in Examples 1, 2 and 3 except that 140 g of indium antimonide was added to the slurry. The target obtained had a density of 99.9%.

### Example 6

Using the same method as in Examples 1, 2 and 3 except that 140 g of indium selenide was added to the slurry. The target obtained had a density of 99.7%.

### Example 7

Using the same method as in Examples 1, 2 and 3 except that 140 g of indium telluride was added to the slurry. The target obtained had a density of 99.9%.

### Example 7

Using the same method as in Examples 1, 2 and 3 except that 140 g of boric acid was added to the slurry. The target obtained had a density of 99.7%.

### Example 8

Using the same method as in Examples 1, 2 and 3 except that 140 g of bismuth(III) phosphate was added to the slurry. The target obtained had a density of 99.9%.

### Example 9

Using the same method as in Examples 1, 2 and 3 except that 140 g of boron(III) phosphate hydrate was added to the slurry. The target obtained had a density of 99.4%.

### Example 10

Using the same method as in Examples 1, 2 and 3 except that 140 g of arsenic(III) oxide was added to the slurry. The target obtained had a density of 99.9%.0

### Example 11

Using the same method as in Examples 1, 2 and 3 except that 140 g of antimony(III) oxide was added to the slurry. The target obtained had a density of 99.8%.

### Example 12

Using the same method as in Examples 1, 2 and 3 except that 140 g of bismuth(III) oxide was added to the slurry. The target obtained had a density of 99.9%.

Thus the efficiency of utilization of an ITO target during the process of sputtering can be improved.

Further, a process is provided by which a large ITO target of an arbitrary shape can be prepared without the use of hazardous materials such as hydrogen chloride or chlorine gases which are both highly toxic to biological organisms.

Furthermore, ITO targets of relative densities greater than 99% of theoretical can be prepared with excellent uniformity of density, stoichiometry, and electrical and thermal conductivities across the target body even with target sizes greater than 250 cm².

What is claimed is:

1. A method of producing a high density ITO target, comprising forming an aqueous slip of ITO powder with ITO powder content greater than 80% by weight, said slip comprising one or more sintering aids in the form of one or more compounds of arsenic, antimony, bismuth, selenium, tellurium and/or boron.

2. A method according to claim 1 where one of the sintering aids is arsenic(III) oxide in a concentration between 0.001% and 1% by weight of dry ITO powder.

3. A method according to claim 1 or 2, where one of the sintering aids is antimony(III) oxide in a concentration between 0.001% and 1% by weight of dry ITO powder.

4. A method according to claim 1, 2 or 3, where one of the sintering aids is bismuth(III) oxide in a concentration between 0.001% and 1% by weight of dry ITO powder.

5. A method according to any preceding claim, where one of the sintering aids is boric acid in a concentration between 0.001% and 1% by weight of dry ITO powder.

6. A method according to any preceding claim, where one of the sintering aids is tellurium(IV) oxide in a concentration between 0.001% and 1% by weight of dry ITO powder.

7. A method according to any preceding claim, where one of the sintering aids is bismuth(III) oxide in a concentration between 0.001% and 1% by weight of ITO powder.

8. A method according to any preceding claim, where one of the sintering aids is indium(III) arsenide in a concentration between 0.001% and 1% by weight of dry ITO powder.

9. A method according to any preceding claim, where one of the sintering aids is indium(III) antimonide in a concentration between 0.001% and 1% by weight of dry ITO powder.

10. A method according to any preceding claim, where one of the sintering aids is indium(III) selenide in a concentration between 0.001% and 1% by weight of dry ITO powder.

11. A method according to any preceding claim, where one of the sintering aids is indium(III) telluride in a concentration between 0.001% and 1% by weight of dry ITO powder.

12. A method according to any preceding claim, where one of the sintering aids is bismuth(III) phosphate in a concentration between 0.001% and 1% by weight of dry ITO powder.

13. A method according to any preceding claim, where one of the sintering aids is boron(III) phosphate in a concentration between 0.001% and 1% by weight of dry ITO powder.

14. A method according to any preceding claim, further comprising casting the slip using a porous plaster of paris mold to produce a ITO green body.

15. A method according to any of claims 1 to 13, further comprising casting the slip using a porous polymer mold fixed in a pressure slip casting machine to yield an ITO green body.

16. A method according to any of claims 1 to 13, further comprising spray drying the slip to produce granulated ITO powder which is compacted into a green body using cold isostatic pressing.

17. The method of claim 14, 15 or 16, further comprising firing the green body in a furnace at peak temperatures of up to 1700° C.

18. A ITO target manufactured using the method of any preceding claim.
